(19) United States
(12) Patent Application Publication
(10) Pub. No.: US 2024/0045604 A1
(43) Pub. Date: Feb. 8, 2024

(54) SELF-ALIGNED TECHNIQUES FOR FORMING CONNECTIONS IN A MEMORY DEVICE

(71) Applicant: Micron Technology, Inc., Boise, ID (US)

(72) Inventors: Zhuo Chen, Boise, ID (US); Beth R. Cook, Boise, ID (US); Dale W. Collins, Boise, ID (US); Muralikrishnan Balakrishnan, Boise, ID (US)

(21) Appl. No.: 17/879,581

(22) Filed: Aug. 2, 2022

(51) Int. Cl. G06F 3/06

(52) U.S. Cl. CPC G06F 3/0635; G06F 3/0604; G06F 3/0679

(57) ABSTRACT

Methods, systems, and devices for self-aligned techniques for forming connections in a memory device are described. A redistribution layer (RDL) for coupling an electrode of a capacitor of a memory cell with a corresponding selector device may be fabricated at a same time or stage as the electrode, using self-aligned techniques. When forming portions of a memory cell, a cavity for the electrode may be etched, and a portion of the RDL that extends from the electrode cavity to a corresponding selector device may also be selectively etched. The resulting cavities may be filled with an electrode material, which may form the electrode and couple the electrode to the corresponding selector device. The resulting memory device may support implementation of a staggered configuration for memory cells, and may include electrodes that share a crystalline structure with one or more corresponding portions of an RDL.

### FIELD OF TECHNOLOGY

The following relates to one or more systems for memory, including self-aligned techniques for forming connections in a memory device.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read (e.g., sense, detect, retrieve, identify, determine, evaluate) a stored state in the memory device. To store information, a component may write (e.g., program, set, assign) the state in the memory device.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source. FeRAM may be able to achieve densities similar to volatile memory but may have non-volatile properties due to the use of a ferroelectric capacitor as a storage device.

### BRIEF DESCRIPTION OF THE DRAWINGS

FIG. 1 illustrates an example of a memory die that supports self-aligned techniques for forming connections in a memory device in accordance with examples as disclosed herein.

FIG. 2 illustrates an example of a processing step that supports self-aligned techniques for forming connections in a memory device in accordance with examples as disclosed herein.

FIG. 3 illustrates an example of a processing step that supports self-aligned techniques for forming connections in a memory device in accordance with examples as disclosed herein.

FIG. 4 illustrates an example of a processing step that supports self-aligned techniques for forming connections in a memory device in accordance with examples as disclosed herein.

FIG. 5 illustrates an example of a processing step that supports self-aligned techniques for forming connections in a memory device in accordance with examples as disclosed herein.

FIG. 6 illustrates an example of a processing step that supports self-aligned techniques for forming connections in a memory device in accordance with examples as disclosed herein.

FIG. 7 illustrates an example of a processing step that supports self-aligned techniques for forming connections in a memory device in accordance with examples as disclosed herein.

FIGS. 8 and 9 show flowcharts illustrating a method or methods that support self-aligned techniques for forming connections in a memory device in accordance with examples as disclosed herein.

### DETAILED DESCRIPTION

Some memory cell arrays (e.g., ferroelectric memory cell arrays) may be manufactured using a process that includes forming a vertical stud. In such examples, a substrate may be formed that includes selector devices. In some cases, the selector devices may be arranged in a grid-like pattern. Interior electrodes (e.g., studs) may be positioned above the substrate and configured to couple with the selector devices. The interior electrodes may be arranged in a staggered (e.g., hexagonal) pattern. The staggered configuration of the interior electrodes (e.g., studs) may support an increased quantity of memory cells within the memory device, an increased performance of memory cells within the memory device, or both. In such configuration, at least some interior electrodes (e.g., electrodes of a capacitor of a memory cell, electrodes coupled with a selector device and digit line) of the memory device may not align with (e.g., couple with) corresponding selector devices at another level of the memory device. For example, the staggered pattern and the grid-like pattern may not align in some cases. Accordingly, a redistribution layer (RDL) may be included in the memory device (e.g., between interior electrodes and a structure that includes the corresponding selector devices) to couple each interior electrode with the corresponding selector device. For example, the RDL may include a pattern of dielectric (e.g., insulating) material and electrode material, which may couple interior electrodes with the corresponding selector devices (e.g., via the electrode material of the RDL). However, manufacturing the RDL may increase manufacturing time, for example, because some RDL material may be deposited, patterned, etched, and filled (e.g., with electrode material). As such, patterning the RDL may increase manufacturing time and cost of production for a memory device.

In order to reduce time and cost for manufacturing the RDL, the RDL may be fabricated together with the interior electrode (e.g., at a same time or stage as fabrication of the interior electrode), using self-aligned techniques that may reduce manufacturing time and costs. For example, when forming portions of a memory cell, a cavity for the interior electrode may be etched, and a portion of the RDL that extends from the interior electrode cavity to a corresponding selector device may be selectively etched. The resulting cavities may be filled with electrode material, which may form the interior electrode and couple the interior electrode to the selector device and support implementation of the staggered configuration for memory cells, without patterning, etching, and filling an RDL (e.g., and thus reducing manufacturing time, complexity, and cost).

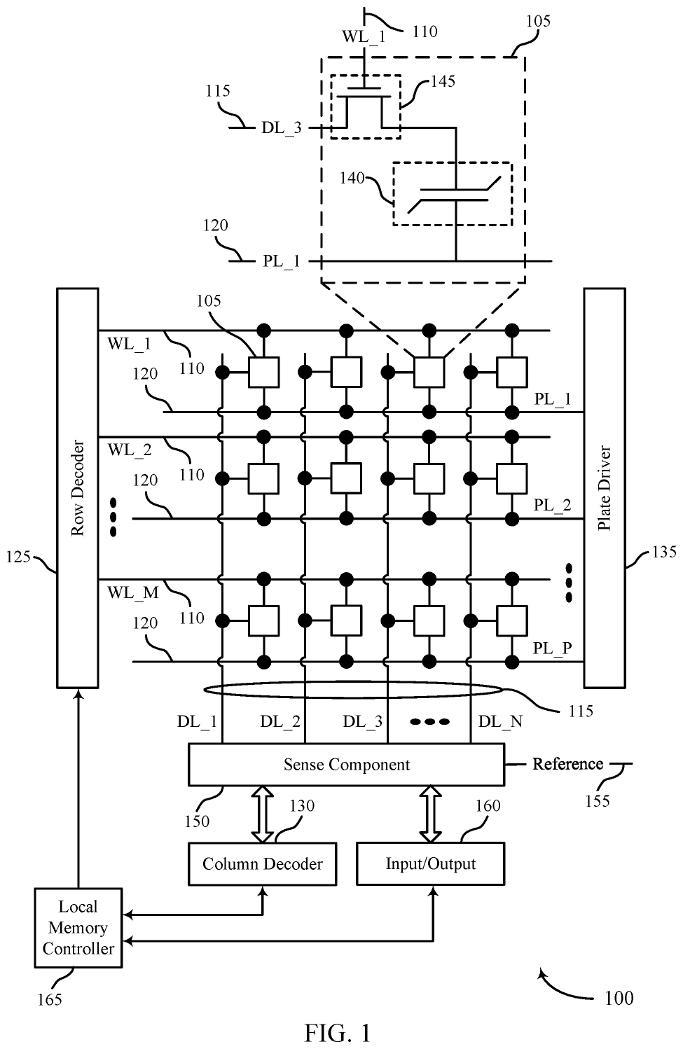

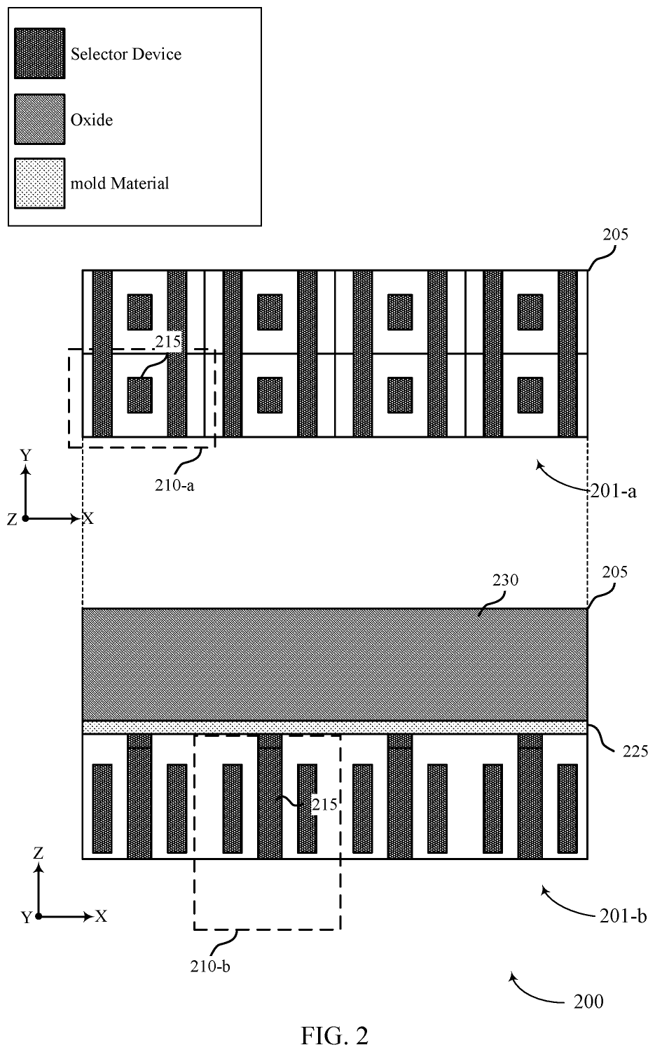

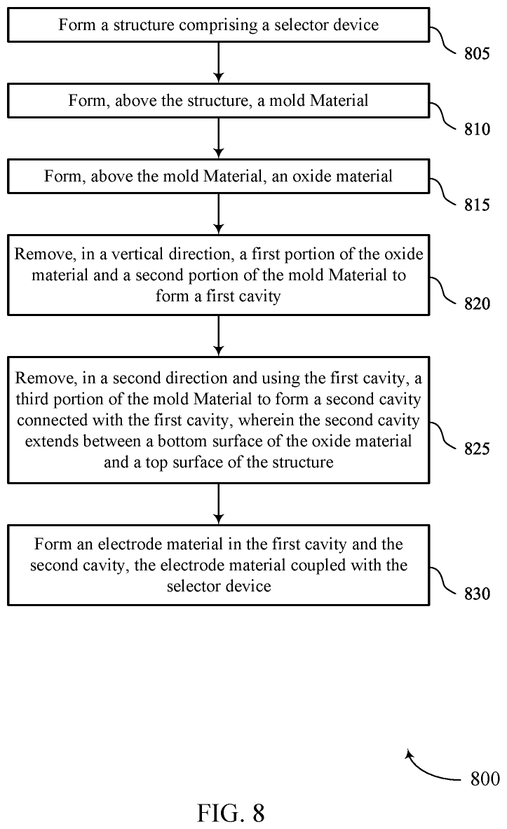

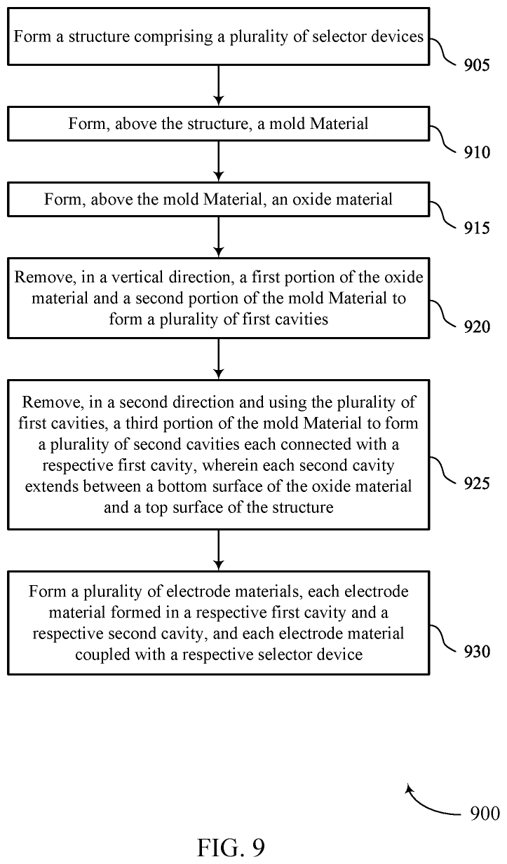

Features of the disclosure are initially described in the context of dies with reference to FIG. 1. Features of the disclosure are described in the context processing steps with reference to FIGS. 2 through 7. These and other features of the disclosure are further illustrated by and described with reference to flowcharts that relate to self-aligned techniques for forming connections in a memory device as described with reference to FIGS. 8 and 9.

FIG. 1 illustrates an example of a memory die 100 that supports self-aligned techniques for forming connections in a memory device in accordance with examples as disclosed herein. In some examples, the memory die 100 may be referred to as a memory chip, a memory device, or an electronic memory apparatus. The memory die 100 may include one or more memory cells 105 that may each be programmable to store different logic states (e.g., programmed to one of a set of two or more possible states). For example, a memory cell 105 may be operable to store one bit of information at a time (e.g., a logic 0 or a logic 1). In some examples, a memory cell 105 (e.g., a multi-level memory cell) may be operable to store more than one bit of information at a time (e.g., a logic 00, logic 01, logic 10, a logic 11).

In some examples, a memory cell 105 may store a state (e.g., a polarization state, a dielectric charge) representative of the programmable states in a capacitor. The memory cell 105 may include a logic storage component, such as capacitor 140, and a switching component 145 (e.g., a cell selection component). A first node of the capacitor 140 may be coupled with the switching component 145 and a second node of the capacitor 140 may be coupled with a plate line 120. The switching component 145 may be an example of a transistor or any other type of switch device that selectively establishes or de-establishes electronic communication between two components. In FeRAM architectures, the memory cell 105 may include a capacitor 140 (e.g., a ferroelectric capacitor) that includes a ferroelectric material to store a charge (e.g., a polarization) representative of the programmable state.

The memory die 100 may include access lines (e.g., word lines 110, digit lines 115, plate lines 120) arranged in a pattern, such as a grid-like pattern. An access line may be a conductive line coupled with a memory cell 105 and may be used to perform access operations on the memory cell 105. In some examples, word lines 110 may be referred to as row lines. In some examples, digit lines 115 may be referred to as column lines or bit lines. References to access lines, row lines, column lines, word lines, digit lines, bit lines, or plate lines, or their analogues, are interchangeable without loss of understanding. Memory cells 105 may be positioned at intersections of the word lines 110, the digit lines 115, or the plate lines 120.

Operations such as reading and writing may be performed on memory cells 105 by activating access lines such as a word line 110, a digit line 115, or a plate line 120. By biasing a word line 110, a digit line 115, and a plate line 120 (e.g., applying a voltage to the word line 110, digit line 115, or plate line 120), a single memory cell 105 may be accessed at their intersection. The intersection of a word line 110 and a digit line 115 in a two-dimensional or in a three-dimensional configuration may be referred to as an address of a memory cell 105. Activating a word line 110, a digit line 115, or a plate line 120 may include applying a voltage to the respective line.

Accessing the memory cells 105 may be controlled through a row decoder 125, a column decoder 130, or a plate driver 135, or any combination thereof. For example, a row decoder 125 may receive a row address from the local memory controller 165 and activate a word line 110 based on the received row address. A column decoder 130 may receive a column address from the local memory controller 165 and activate a digit line 115 based on the received column address. A plate driver 135 may receive a plate address from the local memory controller 165 and activate a plate line 120 based on the received plate address.

Selecting or deselecting the memory cell 105 may be accomplished by activating or deactivating the switching component 145. The capacitor 140 may be in electronic communication with the digit line 115 using the switching component 145. For example, the capacitor 140 may be isolated from digit line 115 when the switching component 145 is deactivated, and the capacitor 140 may be coupled with digit line 115 when the switching component 145 is activated.

A word line 110 may be a conductive line in electronic communication with a memory cell 105 that is used to perform access operations on the memory cell 105. In some architectures, the word line 110 may be in electronic communication with a gate of a switching component 145 of a memory cell 105 and may be operable to control the switching component 145 of the memory cell. In some architectures, the word line 110 may be in electronic communication with a node of the capacitor of the memory cell 105 and the memory cell 105 may not include a switching component.

A digit line 115 may be a conductive line that couples the memory cell 105 with a sense component 150. In some architectures, the memory cell 105 may be selectively coupled with the digit line 115 during portions of an access operation. For example, the word line 110 and the switching component 145 of the memory cell 105 may be operable to selectively couple or isolate the capacitor 140 of the memory cell 105 and the digit line 115. In some architectures, the memory cell 105 may be in electronic communication (e.g., constant) with the digit line 115.

A plate line 120 may be a conductive line in electronic communication with a memory cell 105 that is used to perform access operations on the memory cell 105. The plate line 120 may be in electronic communication with a node (e.g., the cell bottom) of the capacitor 140. The plate line 120 may cooperate with the digit line 115 to bias the capacitor 140 during access operation of the memory cell 105.

The sense component 150 may determine a state (e.g., a polarization state, a charge) stored on the capacitor 140 of the memory cell 105 and determine a logic state of the memory cell 105 based on the detected state. The sense component 150 may include one or more sense amplifiers to amplify the signal output of the memory cell 105. The sense component 150 may compare the signal received from the memory cell 105 across the digit line 115 to a reference 155 (e.g., a reference voltage, a reference line). The detected logic state of the memory cell 105 may be provided as an output of the sense component 150 (e.g., to an input/output 160), and may indicate the detected logic state to another component of a memory device that includes the memory die 100.

The local memory controller 165 may control the operation of memory cells 105 through the various components (e.g., row decoder 125, column decoder 130, plate driver 135, and sense component 150). In some examples, one or more of the row decoder 125, column decoder 130, and plate driver 135, and sense component 150 may be co-located with the local memory controller 165. The local memory controller 165 may be operable to receive one or more of commands or data from one or more different memory controllers (e.g., an external memory controller associated with a host device, another controller associated with the memory die 100), translate the commands or the data (or both) into information that can be used by the memory die 100, perform one or more operations on the memory die 100, and communicate data from the memory die 100 to a host (e.g., a host device) based on performing the one or more operations. The local memory controller 165 may generate row signals and column address signals to activate the target word line 110, the target digit line 115, and the target plate line 120. The local memory controller 165 also may generate and control various signals (e.g., voltages, currents) used during the operation of the memory die 100. In general, the amplitude, the shape, or the duration of an applied voltage or current discussed herein may be varied and may be different for the various operations discussed in operating the memory die 100.

The local memory controller 165 may be operable to perform one or more access operations on one or more memory cells 105 of the memory die 100. Examples of access operations may include a write operation, a read operation, a refresh operation, a precharge operation, or an activate operation, among others. In some examples, access operations may be performed by or otherwise coordinated by the local memory controller 165 in response to various access commands (e.g., from a host device). The local memory controller 165 may be operable to perform other access operations not listed here or other operations related to the operating of the memory die 100 that are not directly related to accessing the memory cells 105.

When forming portions of a memory cell 105, a cavity for an interior electrode (e.g., an electrode of a capacitor 140 that is coupled with digit line 115 via a switching component 145) of the memory cell 105 may be etched, and a portion of the RDL that extends from the interior electrode cavity to a corresponding selector device (e.g., switching component 145) may be selectively etched. The resulting cavities may be filled with electrode material, which may form the interior electrode and couple the interior electrode to the switching component 145 and support implementation of the staggered configuration for memory cells 105, without patterning, etching, and filling an RDL (e.g., and thus reducing manufacturing time, complexity, and cost). After forming the interior electrode of the capacitor 140, a dielectric material (e.g., ferroelectric material) and exterior electrode (e.g., an electrode coupled with a plate line 120) of the capacitor 140 may be formed.

FIG. 2 illustrates an example of a processing step 200 that supports self-aligned techniques for forming connections in a memory device in accordance with examples as disclosed herein. For example, processing step 200 may illustrate a memory device 205 at a stage in processing, manufacturing, or fabricating the memory device (e.g., by a manufacturing system). The memory device 205 may be an example of, or may include, one or more memory dies 100 as described with reference to FIG. 1 (e.g., or may be manufactured to be or include the one or more memory dies). FIG. 2 illustrates a top plan view 201-a and a cross-sectional side view 201-b of the memory device 205.

As the memory device 205 scales to become larger (e.g., based on design or industry considerations), some orthogonal layouts (e.g., grid-like patterns) may not use a full space of a structure for memory cells of the memory device 205. For example, the memory device 205 may include selector devices 210 (e.g., selector device 210-a and selector device 210-b), where the selector devices 210 may be implemented in an orthogonal (e.g., square) layout (e.g., as illustrated by view 201-a). In the orthogonal layout, each memory cell may be located above a respective selector device 210. However, this memory cell layout may cause an overlap or merge between memory cells (e.g., due to a size and position of the memory cells), which may cause some portions (e.g., the merged portions) of an array of memory cells to be formed without a respective top electrode. In a stud-like construction of a memory array, vertical studs may be formed and those studs may be elliptical in shape. With such a configuration, a staggered layout may improve the density of studs in the memory array instead of an orthogonal layout. Thus, the orthogonal layout may limit an amount of memory cells formed in the memory device 205, the reliability of memory cells of the memory device 205 (due to overlap between structures), or both. To increase the amount of memory cells within the memory device 205 without causing an overlap between memory cells, a staggered (e.g., hexagonal) layout for memory cells may be implemented to reduce memory cell overlap.

In such alignments, however, respective interior electrodes of one or more memory cells may not align or be coupled with corresponding selector devices at a lower layer of the memory device. Thus, an RDL may be included in the memory device (e.g., between the interior electrodes and the selector devices) to couple each interior electrode with the corresponding selector device. For example, the RDL may include a pattern of dielectric (e.g., insulating) material and electrode material, which may couple interior electrodes with the corresponding selector devices (e.g., via the electrode material of the RDL). However, manufacturing the RDL may increase manufacturing time, for example, because some RDL material may be deposited, patterned, etched, and filled (e.g., with electrode material). Thus, patterning the RDL may increase manufacturing time and increase cost of production.

In order to reduce time and cost for manufacturing the RDL, the RDL may be fabricated together with the interior electrode (e.g., at a same time as fabrication of the interior electrode), using self-aligned techniques that may reduce manufacturing time and costs. For example, when forming portions of a memory cell, a cavity for the interior electrode may be etched, and a portion of the RDL that extends from the interior electrode cavity to a corresponding selector device may also be selectively etched. The resulting cavities may be filled with electrode material, which may form the interior electrode and couple the interior electrode to the selector device and support implementation of the staggered geometry alignment for memory cells, without patterning, etching, and filling an RDL (e.g., and thus reducing manufacturing time, complexity, and cost).

Prior to forming the interior electrode, one or more portions of the memory device 205 may be formed, including one or more selector devices 210 (e.g., one or more selector devices 210 included in a structure for the selector devices 210). The selector devices may be an example of a transistor, and may each include a respective TFT pillar 215 and a word line (e.g., coupled with the TFT pillar 215). In some cases, the TFT pillar 215 may have a first width (e.g., a width of 7 nm) and may be spaced from a next TFT pillar 215 by a defined distance (e.g., a distance of 30.5 nm). After forming structure that includes the selector devices 210, a mold material 225 may be formed above the structure that includes the one or more selector devices 210. After deposition of the mold material 225, an oxide material 230 may be deposited above the mold material 225. The mold material 225 may be located at the RDL and may be used to form the RDL for the memory device 205.

For example, the mold material 225 may be used as an RDL mold, placeholder, or the like. As such, the mold material 225 may enable the RDL self-alignment techniques described herein. In some examples, the mold material 225 may be a high kappa (Hi-K) dielectric oxide material such as an amorphous aluminum oxide (AlOx) material. In such examples, the mold material 225 may have a higher etch rate than the oxide material 230 in a hydrofluoric acid (HF) etching procedure. In some other examples, the mold material 225 may be a low defect carbon material, that may be resistant to the HF but may be etched using ozone. The oxide material 230 may have a lower etch rate in HF or ozone than the mold material 225 and thus the mold material may be selectively etched while the oxide material 230 may not be etched (e.g., or may not substantially be etched).

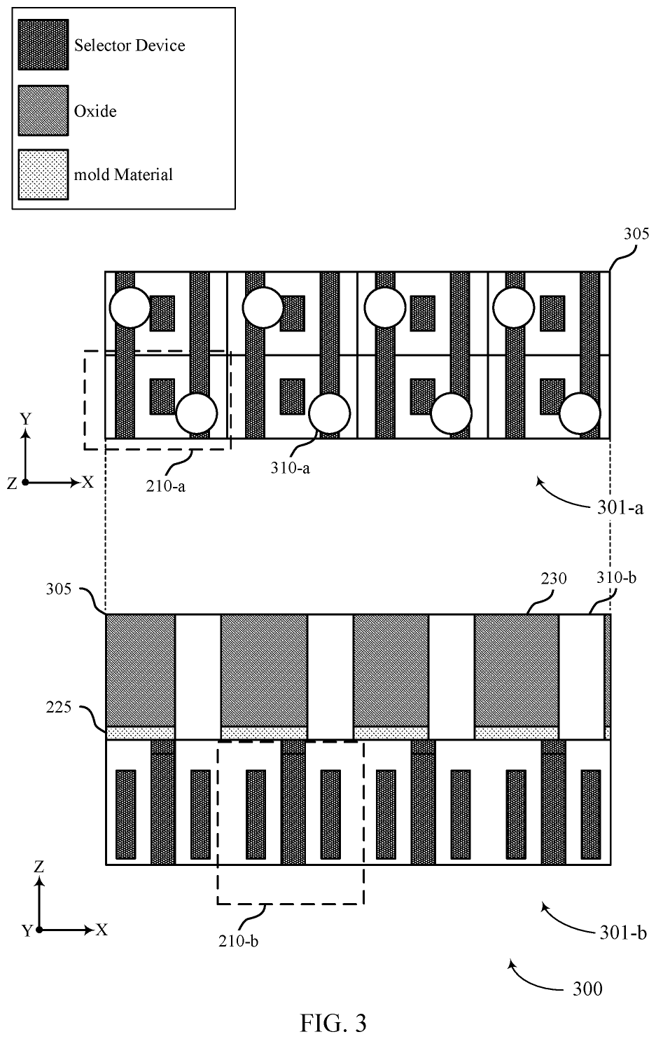

FIG. 3 illustrates an example of a processing step 300 that supports self-aligned techniques for forming connections in a memory device in accordance with examples as disclosed herein. For example, processing step 300 may illustrate a memory device 305 at a stage in processing, manufacturing, or fabricating the memory device. The memory device 305 may represent a continuation of one or more processing, manufacturing, or fabrication procedures performed on the memory device 205. FIG. 3 illustrates a top plan view 301-a and a cross-sectional side view 301-b of the memory device 305. The memory device 305 may include selector devices 210 (e.g., each including a respective TFT pillar 215 and word line), a mold material 225, and an oxide material 230, for example, as described with reference to FIG. 2

FIG. 3 illustrates an etching procedure (e.g., material removal procedure or process) that may be performed to etch cavities 310 (e.g., cavity 310-a and cavity 310-b) in the memory device 305. Each cavity 310 may correspond to locations for a first electrode (e.g., interior electrode, stud) for memory cells of the memory device 305. In some cases, a dry etching procedure may be used to form the cavities 310 by etching the cavity through the oxide material 230 and the mold material 225 (e.g., at least a portion of the mold material 225). The dry etching procedure may, for example, be performed by a laser or plasma and, in some cases, may leverage different material properties of the mold material 225 and oxide material 230.

For example, in cases where the mold material 225 is AlOx, the mold material 225 may act as a hard mask and resist or stop the dry etch. Thus, the dry etching procedure may etch part of the way through the mold material 225 (e.g., etch a relatively small portion of the mold material 225) and may stop before etching through the mold material 225. As such, the mold material 225 may form an etch stop layer (e.g., and may protect one or more materials beneath the mold material 225). In cases when the mold material 225 is a low defect carbon material, the etching procedure may remove the oxide material using the dry etch procedure and subsequently etch through at least a portion (e.g., if not all) of the low defect carbon mold material 225.

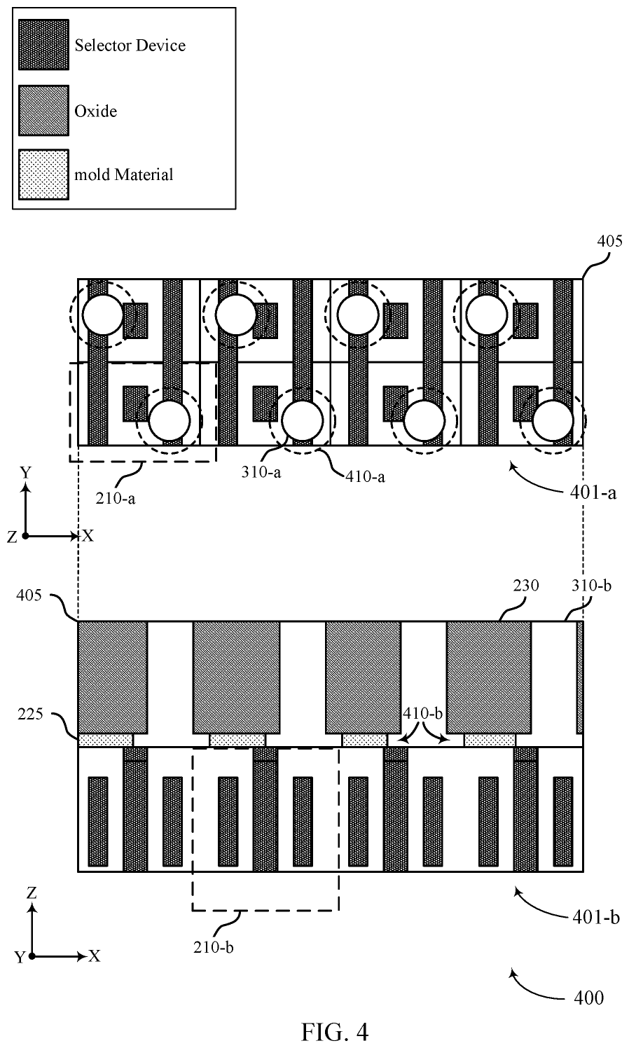

FIG. 4 illustrates an example of a processing step 400 that supports self-aligned techniques for forming connections in a memory device in accordance with examples as disclosed herein. For example, processing step 400 may illustrate a memory device 405 at a stage in processing, manufacturing, or fabricating the memory device. The memory device 405 may represent a continuation of one or more processing, manufacturing, or fabrication procedures performed on the memory device 305. FIG. 4 illustrates a top plan view 401-a and a cross-sectional side view 401-b of the memory device 405. The memory device 405 may include selector devices 210 (e.g., each including a respective TFT pillar 215 and word line), a mold material 225, and an oxide material 230, for example, as described with reference to FIG. 2. Additionally, the memory device 405 may include cavities 310 (e.g., cavities 310-a and 310-b) as described herein with reference to FIG. 3.

FIG. 4 illustrates an etching procedure that may be performed to etch a cavity 410 (e.g., a cavity 410-a, a cavity 410-b, or both) in the memory device 405. For example, a selective etch may be performed to etch the mold material 225 in a horizontal or radial direction (e.g., radially out from a center of a cavity 310) to form a cavity 410 that is connected to the cavity 310. The selective etch may be an example of a wet etch (e.g., chemical etch) and may be utilized to etch the mold material 225. That is, the selective etch may etch only the mold material 225, while maintaining (e.g., refraining from etching, partially or minimally etching) the oxide material 230.

The selective etch may be due to the composition of the mold material 225. For example, if the mold material 225 is AlOx, HF acid or one or more additional or alternative chemicals may be used to etch the mold material 225 in the horizontal direction, while maintaining the oxide material 230 (e.g., because the oxide material 230 may be resistant, or relatively resistant, to the HF acid and/or other chemical(s)). Alternatively, if the mold material 225 is low defect carbon, an ozone flow (e.g., 03 plasma) or one or more other additional or alternative chemicals may be utilized to etch the mold material 225 horizontally and maintain the oxide material 230 (e.g., because the oxide material 230 may be resistant, or relatively resistant, to the ozone and/or other chemical(s)). Thus, the cavity 410 may be etched and formed in connection with the cavity 310.

Alternatively, the selective etching procedure may be an example of an atomic layer etching procedure. The atomic layer etching may be configured based on the composition of the oxide material 230 and the mold material 225. For example, if the mold material 225 is made up AlOx, the atomic layer etching may be configured with a reactive species to target the AlOx of the mold material 225 and maintain (e.g., refrain from etching, partially or minimally etch) the oxide material 230.

In any of the examples described herein, the selective etching procedure may be tuned or adjusted to control an amount (e.g., distance or length) of the mold material 225 that is etched. This may support alignment of each cavity 410 with a corresponding selector device 210, which may further support coupling the associated interior electrode with the selector device. For example, the selective etching procedure may be adjusted to allow the cavity 410 to align with the TFT pillar 215 (e.g., at least a portion of the TFT pillar 215). In some cases, the selective etching procedure may expose at least a portion of each selector device 210 (e.g., for future coupling with the interior electrode).

In some cases, the selective etch may be repeated iteratively to remove a desired or specified amount of the mold material 225. For example, the memory device 405 may be weighed, and the selective etching procedure may be done a first time after weighing the memory device 405. After completion of the selective etching procedure, the memory device 405 may be weighed again to determine how much mold material 225 was lost during the selective etching (e.g., to determine how far the mold material 225 was etched). This process may be iteratively performed until a desired or specified cavity 410 dimension (e.g., length, distance, mass removed) is achieved.

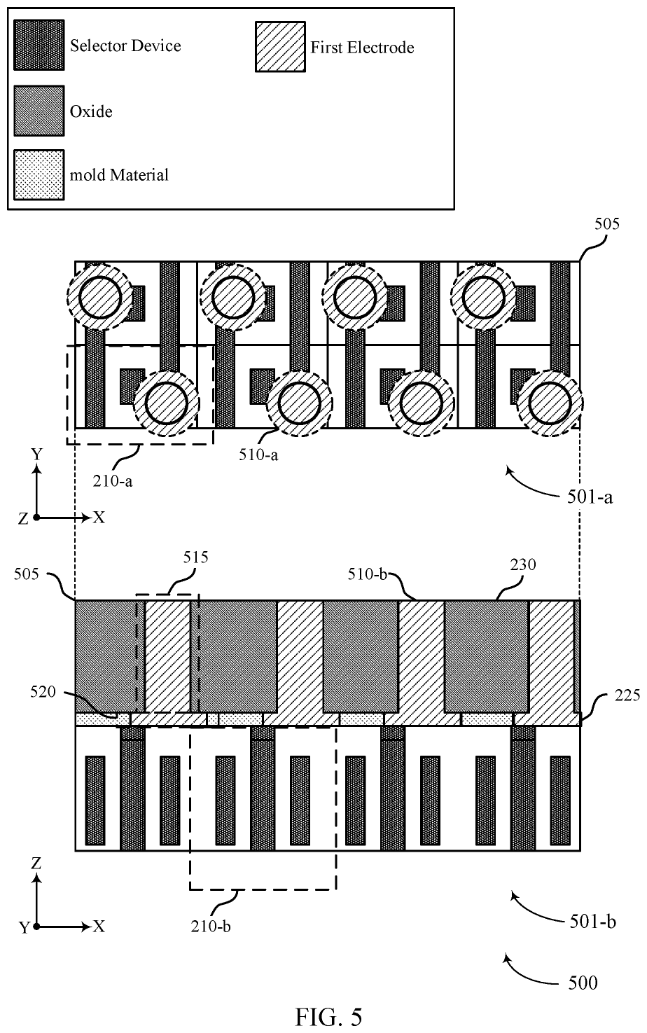

FIG. 5 illustrates an example of a processing step 500 that supports self-aligned techniques for forming connections in a memory device in accordance with examples as disclosed herein. For example, processing step 500 may illustrate a memory device 505 at a stage in processing, manufacturing, or fabricating the memory device. The memory device 505 may represent a continuation of one or more processing, manufacturing, or fabrication procedures performed on memory device 405. FIG. 5 illustrates a top plan view 501-a and a cross-sectional side view 501-b of the memory device 505. The memory device 505 may include selector devices 210 (e.g., each including a respective TFT pillar 215 and wordline), a mold material 225, and an oxide material 230, for example, as described with reference to FIG. 2.

Each cavity 310 and the cavity 410 may be filled with an electrode material (e.g., titanium nitride (TiN) or other electrode material) to create multiple, respective first electrodes 510 (e.g., studs, interior electrodes). The cavity 310 and the cavity 410 may be filled, for example, using an atomic layer deposition, or another type of deposition. Each cavity 310 and cavity 410 may be filled (e.g., together, at a same time) to form the first electrodes 510 (e.g., first electrode 510-a and first electrode 510-b), where each first electrode 510 may include a respective base and a respective pillar. For example, the memory device 505 may include a first portion 515 of the first electrode 510 (e.g., corresponding to cavity 310 described with reference to FIG. 3) and a second portion 520 of the first electrode 510 (e.g., corresponding to cavity 410 described with reference to FIG. 4). In some examples, the first portion 515 may be referred to as a pillar of the first electrode 510 and the second portion 520 may be referred as a base of the first electrode 510.

A pillar of a first electrode 510 may be a portion of electrode material that fills the cavity 310, while a base of the first electrode 510 may be a portion of electrode material that fills the cavity 410. The base may represent a first cylindrical structure having a first width and a first height, and the pillar may represent a second cylindrical structure having a second width and a second height, wherein the first height is less than the second height and the first width is greater than the second width.

Additionally, each first electrode 510 (e.g., stud) and the corresponding selector device 210 may be coupled based on the formation of the first electrodes 510. For example, based on the length of a respective cavity 410 (e.g., as etched), the respective base of each first electrode 510 may at least partially overlap with the TFT pillar 215 of the corresponding selector device 210 (e.g., may align in the vertical direction). In some cases, the base of one or more first electrodes 510 may fully overlap with the TFT pillar 215 of the corresponding selector device(s) 210 based on the length of the respective cavity 410. In some cases, the bases of the first electrodes 510 may be considered part of the RDL (e.g., a part of the RDL used to couple each of the first electrodes 510 with a corresponding selector device 210).

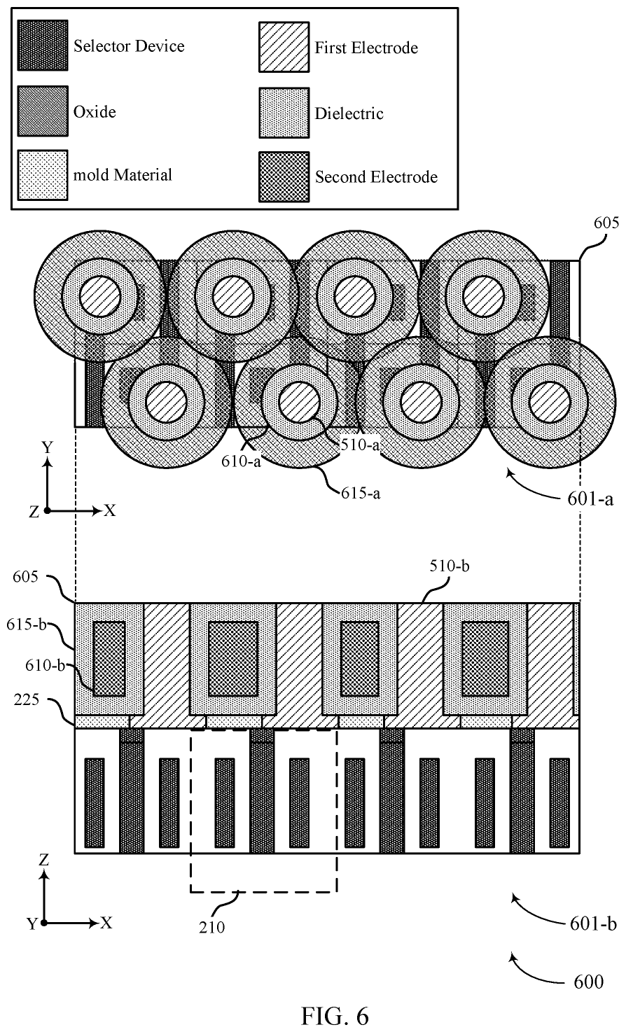

FIG. 6 illustrates an example of a processing step 600 that supports self-aligned techniques for forming connections in a memory device in accordance with examples as disclosed herein. For example, processing step 600 may illustrate a memory device 605 at a stage in processing, manufacturing, or fabricating the memory device. The memory device 605 may represent a continuation of one or more processing, manufacturing, or fabrication procedures performed on memory device 505. FIG. 6 illustrates a top plan view 601-a and a cross-sectional side view 601-b of the memory device 605. The memory device 605 may include selector devices 210 (e.g., each including a respective TFT pillar 215 and word line) and a mold material 225, for example, as described with reference to FIG. 2. Additionally, the memory device 605 may include first electrodes 510 as described herein with reference to FIG. 5.

In some cases, after formation of the first electrodes 510, the mold material 225 may be crystallized via rapid thermal processing (e.g., via a heat treatment). Subsequently, the oxide material 230 may be etched to create a third cavity for a dielectric material 610 (e.g., dielectric material 610-a, dielectric material 610-b, or both) and a second electrode 615 (e.g., dielectric material 615-a, dielectric material 615-b, or both). For example, to remove the oxide material 230 from the memory device 605, HF acid or one or more other additional or alternative chemicals may be used to etch (e.g., remove) the oxide material 230. In some cases, the mold material 225 may be crystallized to prevent etching of the mold material 225 by the HF acid and/or other chemical(s). For example, the crystallized mold material may have a low etch rate (e.g., relatively low, when compared with the oxide material 230) when HF acid is used to exhume (e.g., remove) the oxide material 230. Thus, the oxide material 230 may be removed without etching any of the corresponding mold material 225 (e.g., or with relatively little etching of the mold material 225, minimal etching of the mold material 225).

After removal of the oxide material 230, the dielectric material 610 may be deposited onto the walls of third cavity using an atomic layer deposition. For example, the dielectric material 610 may be deposited and grow along sidewalls, bottom walls, and top walls of the third cavity. As such, the dielectric material 610 may be deposited and grow along sidewalls and bottom walls of the first electrodes 510, top walls of the mold material 225, and bottom walls of an upper layer material (e.g., above the first electrodes 510, for holding the first electrodes 510). The upper layer material is not shown in FIG. 6 and it may cover portions of the third cavity and be open in other portions of the third cavity. The openings of the upper layer material may be used as access for the deposition of the dielectric materials 610 and other materials. Subsequently, electrode material for forming the second electrode 615 may be deposited (e.g., using atomic layer deposition) in a remaining portion of the third cavity to form the top electrode. For example, the second electrode 615 may be deposited and grow on sidewalls, top walls, and bottom walls of the dielectric material 610. Thus, the memory device 605 and the memory device 605 may be formed in the hexagonal pattern.

The fabrication techniques described herein may support one or more functions of the memory device 605 to store data (e.g., after one or more additional processing techniques). For example, a selector device 210 may be activated to access a first electrode 510 of a memory cell by supplying a voltage to a gate (e.g., gate electrode) of the selector device 210. Subsequently, an access voltage (e.g., a digit line voltage) may be applied to the selector device 210, and via the selector device to the first electrode 510. A second access voltage (e.g., a plate voltage, plate line voltage) may be applied to a second electrode 615 of the memory cell (e.g., via a plate line, such as a plate line shared by multiple memory cells) to access the memory cell. The dielectric material 610 between the first electrode 510 and the second electrode 615 may electrically insulates the first electrode 510 from the second electrode 615. Additionally, the dielectric material 610 may be or include a material (e.g., ferroelectric material) used to store a logic state of the memory cell (e.g., in ferroelectric random access memory (FeRAM)). Thus, the memory device 605 may be used to store and read data.

In some cases, a first electrode 510, a second electrode 615, or a dielectric material 610 may be shared by, or associated with, more than one memory cell. For example, a first portion of a dielectric material (e.g., between a first electrode 510 and a second electrode 615) may represent a first memory cell and may be used to store a logic state. Additionally, a second portion of the same dielectric material (e.g., between another first electrode 510 and another corresponding second electrode 615) may represent a second memory cell and may be used to store a respective logic state. In some cases, one or more dielectric materials 610 of different memory cells may be coupled, or may share a same material.

Using the techniques described herein, a respective base and pillar of each first electrode 510 may be formed together, resulting in a first electrode 510 having a crystalline structure (e.g., an uninterrupted crystalline structure, a shared crystalline structure). As such, each first electrode 510 may be formed without an edge grain in the electrode material between the pillar and the base of the first electrode 510 (e.g., where other manufacturing techniques may result in an edge grain between electrode material of the first electrode 510 and electrode material of an RDL). For example, there may be no edge grain between the pillar and the base of the first electrodes 510 at a center axis of the first electrodes (e.g., a center axis of the pillar, of the base), among other locations.

Further, because each first electrode 510 may be formed using atomic layer deposition, the pillar and the base of a first electrode 510 may share an edge grain at the boundary between the first electrode 510, a corresponding dielectric material 610, and a corresponding mold material 225 (e.g., the edge grain may continuously follow the boundary between the first electrode 510 and each of these materials). For example, the crystalline structure of the first electrode 510 may include an edge grain structure that follows a first surface between the pillar and a dielectric material 610 (e.g., on a sidewall of the dielectric material 610) and follows a second surface between the base and the dielectric material 610 (e.g., on a bottom side of the dielectric material 610), where the edge grain structure may extend from (e.g., across) the first surface to the second surface. In some cases, the edge grain structure of a first electrode 510 may follow the outside edges of the first electrode 510 (e.g., including the base and the pillar) that are in contact with other materials or structures (e.g., the silhouette of the first electrode 510, the outline of the first electrode 510).

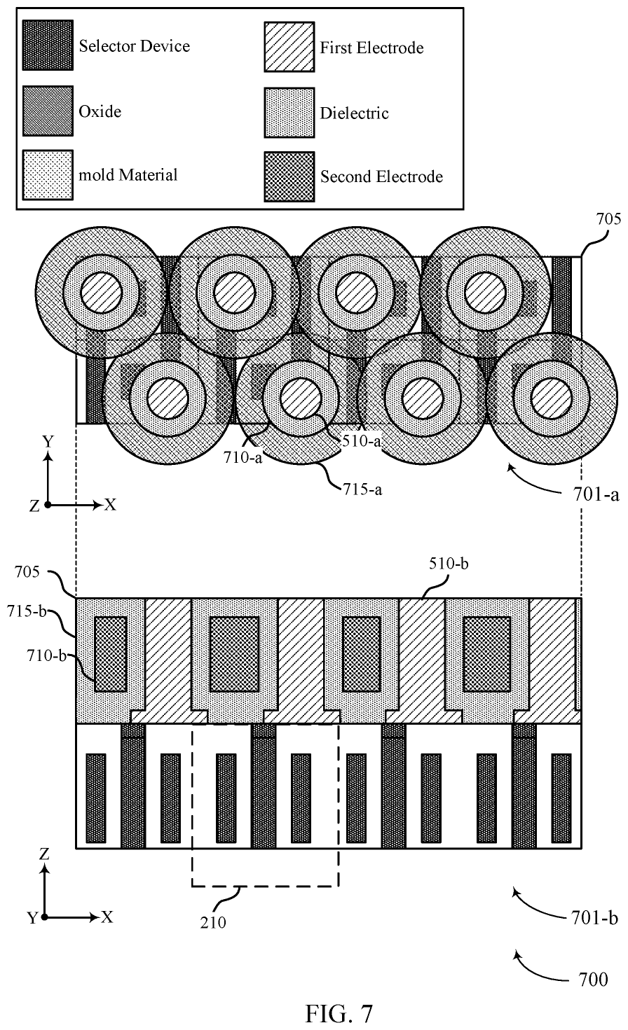

FIG. 7 illustrates an example of a processing step 700 that supports self-aligned techniques for forming connections in a memory device in accordance with examples as disclosed herein. For example, processing step 700 may illustrate a memory device 705 at a stage in processing, manufacturing, or fabricating the memory device. The memory device 705 may represent a continuation of one or more processing, manufacturing, or fabrication procedures performed on memory device 505, and may represent an alternative configuration to the memory device 605. FIG. 7 illustrates a top plan view 701-a and a cross-sectional side view 701-b of the memory device 705. The memory device 705 may include selector devices 210 (e.g., each including a respective TFT pillar 215 and word line), for example, as described with reference to FIG. 2. Additionally, the memory device 705 may include first electrodes 510 as described herein with reference to FIG. 5.

FIG. 7 represents an alternative example as those described in FIG. 6. Specifically, the mold material 225 may be formed of carbon (or some similar material) instead of an oxide. In such examples, some of the processing techniques described with reference to FIGS. 2-6 may be modified based on the different mold material and the resulting structure may have some differences.

In the examples of FIG. 7, after formation of the first electrodes 510, if the mold material 225 is the AlOx and is not crystallized, HF acid (e.g., or one or more other additional or alternative chemicals) may be used to etch (e.g., remove) the oxide material 230 and the mold material 225 to form a third cavity for forming or depositing dielectric material 710 (e.g., dielectric material 710-a, dielectric material 710-b, or both) and a second electrode 715 (e.g., dielectric material 715-a, dielectric material 715-b, or both). Similarly (e.g., in some other examples), if the mold material 225 is the low defect carbon, the HF acid (e.g., or one or more other additional or alternative chemicals) may be used to etch (e.g., remove) the oxide material 230 and ozone (e.g., or one or more other additional or alternative chemicals) may be used to etch (e.g., remove) the mold material 225 to form the third cavity.

After forming the third cavity, the dielectric material 710 (e.g., a ferroelectric material) may be deposited onto the walls of the first electrodes 510 (e.g., using atomic layer deposition). For example, the dielectric material 710 may be deposited and grow along sidewalls, bottom walls, and top walls of the third cavity. As such, the dielectric material 610 may be deposited and grow along sidewalls and bottom walls of the first electrodes 510, top walls of the structure including the selector devices 210, and bottom walls of an upper layer material (e.g., above the first electrodes 510, for holding the first electrodes 510). Thus, the dielectric material may fill, or at least partially fill, a space previously taken up by the mold material 225. Subsequently, electrode material for forming the second electrodes 715 may be deposited (e.g., using atomic layer deposition) in the remaining portion of the third cavity, to form a top electrode for a memory cell. For example, the second electrode 715 may be deposited and grow on sidewalls, top walls, and bottom walls of the dielectric material 710.

Similar to the memory device 605 as described herein with reference to FIG. 6, the fabrication techniques described herein may support one or more functions of the memory device 705 to store data (e.g., after one or more additional processing techniques). For example, a respective selector device 210 associated with a memory cell may be used to activate and supply an access voltage (e.g., a digit line voltage) to a corresponding first electrode 510. Similarly, a second access voltage (e.g., a plate voltage, plate line voltage) may be applied to a second electrode 715 of the memory cell to access the memory cell. The dielectric material 710 may electrically insulate the first electrode 510 from the second electrode 615, and may additionally be or include a material (e.g., ferroelectric material) used to store a logic state of the memory cell (e.g., in FeRAM). As described with reference to FIG. 6, a first electrode 510, a second electrode 715, or a dielectric material 710 may be shared by, or associated with, more than one memory cell.

As described with reference to FIGS. 5 and 6, a respective base and pillar of each first electrode 510 may be formed together, resulting in a first electrode 510 having a crystalline structure (e.g., an uninterrupted crystalline structure, a shared crystalline structure). As such, each first electrode 510 may be formed without an edge grain in the electrode material between the pillar and the base of the first electrode 510 (e.g., where other manufacturing techniques may result in an edge grain between electrode material of the first electrode 510 and electrode material of an RDL). For example, there may be no edge grain between the pillar and the base of the first electrodes 510 at a center axis of the first electrodes (e.g., a center axis of the pillar, of the base), among other locations.

Further, as described with reference to FIGS. 5 and 6, because each first electrode 510 may be formed using atomic layer deposition, the pillar and the base of a first electrode 510 may share an edge grain at the boundary around the outside edges (e.g., outline, silhouette) of the first electrode 510 (e.g., an edge grain structure may follow a first surface and a second surface between the first electrode 510 and another structure or material, and may extend from the first surface to the second surface).

FIG. 8 shows a flowchart illustrating a method 800 that supports self-aligned techniques for forming connections in a memory device in accordance with examples as disclosed herein. The operations of method 800 may be implemented by a manufacturing system or its components as described herein. For example, the operations of method 800 may be performed by a manufacturing system as described with reference to FIGS. 1 through 7. In some examples, a manufacturing system may execute a set of instructions to control the functional elements of the device to perform the described functions. Additionally, or alternatively, the manufacturing system may perform aspects of the described functions using special-purpose hardware.

At 805, the method may include forming a structure including a selector device. The operations of 805 may be performed in accordance with examples as disclosed herein.

At 810, the method may include forming, above the structure, a mold material. The operations of 810 may be performed in accordance with examples as disclosed herein.

At 815, the method may include forming, above the mold material, an oxide material. The operations of 815 may be performed in accordance with examples as disclosed herein.

At 820, the method may include removing, in a vertical direction, a first portion of the oxide material and a second portion of the mold material to form a first cavity. The operations of 820 may be performed in accordance with examples as disclosed herein.

At 825, the method may include removing, in a second direction and using the first cavity, a third portion of the mold material to form a second cavity connected with the first cavity, where the second cavity extends between a bottom surface of the oxide material and a top surface of the structure. The operations of 825 may be performed in accordance with examples as disclosed herein.

At 830, the method may include forming an electrode material in the first cavity and the second cavity, the electrode material coupled with the selector device. The operations of 830 may be performed in accordance with examples as disclosed herein.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for forming a structure including a selector device; forming, above the structure, a mold material; forming, above the mold material, an oxide material; removing, in a vertical direction, a first portion of the oxide material and a second portion of the mold material to form a first cavity; removing, in a second direction and using the first cavity, a third portion of the mold material to form a second cavity connected with the first cavity, where the second cavity extends between a bottom surface of the oxide material and a top surface of the structure; and forming an electrode material in the first cavity and the second cavity, the electrode material coupled with the selector device.
Aspect 2: The method, apparatus, or non-transitory computer-readable medium of aspect 1 where at least a portion of the third portion of the mold material is aligned in the vertical direction with at least a portion of the selector device.
Aspect 3: The method, apparatus, or non-transitory computer-readable medium of any of aspects 1 through 2 where removing the third portion of the mold material exposes at least a portion of the selector device and forming the electrode material causes the electrode material to couple with the at least the portion of the selector device.
Aspect 4: The method, apparatus, or non-transitory computer-readable medium of any of aspects 1 through 3, further including operations, features, circuitry, logic, means, or instructions, or any combination thereof for removing, after forming the electrode material, the oxide material to form a third cavity; lining the third cavity with a dielectric material after removing the oxide material; and filling a remainder of the third cavity with a second electrode material after lining the third cavity with the dielectric material.
Aspect 5: The method, apparatus, or non-transitory computer-readable medium of aspect 4, further including operations, features, circuitry, logic, means, or instructions, or any combination thereof for heating the mold material to alter a crystalline structure of the mold material before removing the oxide material.
Aspect 6: The method, apparatus, or non-transitory computer-readable medium of any of aspects 4 through 5 where the electrode material includes a bottom electrode coupled with the selector device and the second electrode material includes a top electrode associated with a plate line.
Aspect 7: The method, apparatus, or non-transitory computer-readable medium of any of aspects 1 through 6, further including operations, features, circuitry, logic, means, or instructions, or any combination thereof for removing, after forming the electrode material, the oxide material and the mold material to form a third cavity; lining the third cavity with a dielectric material after removing the oxide material; and filling a remainder of the third cavity with a second electrode material after lining the third cavity with the dielectric material.
Aspect 8: The method, apparatus, or non-transitory computer-readable medium of any of aspects 1 through 7 where removing the first portion of the oxide material and the second portion of the mold material includes operations, features, circuitry, logic, means, or instructions, or any combination thereof for performing an etching process on the first portion of the oxide material and the second portion of the mold material and stopping the etching process before etching through the mold material.
Aspect 9: The method, apparatus, or non-transitory computer-readable medium of any of aspects 1 through 8 where removing the third portion of the mold material includes operations, features, circuitry, logic, means, or instructions, or any combination thereof for performing a chemically selective etch on the mold material.
Aspect 10: The method, apparatus, or non-transitory computer-readable medium of any of aspects 1 through 9 where forming the electrode material includes operations, features, circuitry, logic, means, or instructions, or any combination thereof for performing atomic layer deposition of the electrode material within the first cavity and the second cavity.
Aspect 11: The method, apparatus, or non-transitory computer-readable medium of any of aspects 1 through 10 where the mold material includes an amorphous aluminum oxide material or a carbon material and the electrode material includes a titanium nitride material.
Aspect 12: The method, apparatus, or non-transitory computer-readable medium of any of aspects 1 through 11 where the third portion of the mold material includes a ring of the mold material that surrounds the first cavity.

FIG. 9 shows a flowchart illustrating a method 900 that supports self-aligned techniques for forming connections in a memory device in accordance with examples as disclosed herein. The operations of method 900 may be implemented by a manufacturing system or its components as described herein. For example, the operations of method 900 may be performed by a manufacturing system as described with reference to FIGS. 1 through 7. In some examples, a manufacturing system may execute a set of instructions to control the functional elements of the device to perform the described functions. Additionally, or alternatively, the manufacturing system may perform aspects of the described functions using special-purpose hardware.

At 905, the method may include forming a structure including a plurality of selector devices. The operations of 905 may be performed in accordance with examples as disclosed herein.

At 910, the method may include forming, above the structure, a mold material. The operations of 910 may be performed in accordance with examples as disclosed herein.

At 915, the method may include forming, above the mold material, an oxide material. The operations of 915 may be performed in accordance with examples as disclosed herein.

At 920, the method may include removing, in a vertical direction, a first portion of the oxide material and a second portion of the mold material to form a plurality of first cavities. The operations of 920 may be performed in accordance with examples as disclosed herein.

At 925, the method may include removing, in a second direction and using the plurality of first cavities, a third portion of the mold material to form a plurality of second cavities each connected with a respective first cavity, where each second cavity extends between a bottom surface of the oxide material and a top surface of the structure. The operations of 925 may be performed in accordance with examples as disclosed herein.

At 930, the method may include forming a plurality of electrode materials, each electrode material formed in a respective first cavity and a respective second cavity, and each electrode material coupled with a respective selector device. The operations of 930 may be performed in accordance with examples as disclosed herein.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:
Aspect 13: A method, apparatus, or non-transitory computer-readable medium including operations, features, circuitry, logic, means, or instructions, or any combination thereof for forming a structure including a plurality of selector devices; forming, above the structure, a mold material; forming, above the mold material, an oxide material; removing, in a vertical direction, a first portion of the oxide material and a second portion of the mold material to form a plurality of first cavities; removing, in a second direction and using the plurality of first cavities, a third portion of the mold material to form a plurality of second cavities each connected with a respective first cavity, where each second cavity extends between a bottom surface of the oxide material and a top surface of the structure; and forming a plurality of electrode materials, each electrode material formed in a respective first cavity and a respective second cavity, and each electrode material coupled with a respective selector device.
Aspect 14: The method, apparatus, or non-transitory computer-readable medium of aspect 13, further including operations, features, circuitry, logic, means, or instructions, or any combination thereof for removing, after forming the plurality of electrode materials, the oxide material to form a plurality of third cavities; lining each of the plurality of third cavities with a dielectric material after removing the oxide material; and filling a respective remainder of each of the plurality of third cavities with a second electrode material after lining the plurality of third cavities with the dielectric material.
Aspect 15: The method, apparatus, or non-transitory computer-readable medium of any of aspects 13 through 14, further including operations, features, circuitry, logic, means, or instructions, or any combination thereof for removing, after forming the plurality of electrode materials, the oxide material and the mold material to form a plurality of third cavities; lining each of the plurality of third cavities with a dielectric material after removing the oxide material; and filling a respective remainder of each of the plurality of third cavities with a second electrode material after lining the plurality of third cavities with the dielectric material.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:
Aspect 16: An apparatus, including: a memory cell including: a first electrode including a pillar having a first width and a base having a second width greater than the first width, the base and the pillar sharing a crystalline structure; a second electrode; and a dielectric material positioned between the first electrode and the second electrode, the dielectric material electrically insulating the first electrode from the second electrode; and a selector device for the memory cell, the selector device coupled with the base of the first electrode of the memory cell.
Aspect 17: The apparatus of aspect 16, where the pillar of the first electrode has a first height, and the base of the first electrode includes a pillar having a second height less than the first height.
Aspect 18: The apparatus of any of aspects 16 through 17, where at least a portion of the base of the first electrode is electrically coupled with at least a portion of the selector device.
Aspect 19: The apparatus of any of aspects 16 through 18, further including: a second memory cell including: a third electrode including a second pillar having a third width and a second base having a fourth width greater than the third width, the second base and the second pillar sharing a crystalline structure; a portion of the second electrode; and a portion of the dielectric material, the portion of the dielectric material positioned between the third electrode and the portion of the second electrode and electrically insulating the third electrode from the second electrode; and a second selector device for the second memory cell, the second selector device coupled with the base of the third electrode of the second memory cell.
Aspect 20: The apparatus of aspect 19, further including: a mold material occupying a space between the base of the first electrode and the second base of the third electrode, the mold material below the dielectric material.
Aspect 21: The apparatus of aspect 20, where the mold material includes an oxide material or a carbon material.
Aspect 22: The apparatus of any of aspects 19 through 21, where the dielectric material occupies a space between the base of the first electrode and the second base of the third electrode.
Aspect 23: The apparatus of any of aspects 16 through 22, where the crystalline structure of the first electrode is uninterrupted between the pillar and the base along a center line of the first electrode.
Aspect 24: The apparatus of any of aspects 16 through 23, where the crystalline structure of the first electrode includes an edge grain structure that follows a first surface between the pillar and the dielectric material and a second surface between the base and the dielectric material, the edge grain structure extending from the first surface to the second surface.
Aspect 25: The apparatus of any of aspects 16 through 24, where: the first electrode includes a titanium nitride material; and the dielectric material includes a ferroelectric material.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a structure comprising a selector device;
forming, above the structure, a mold material;
forming, above the mold material, an oxide material;
removing, in a vertical direction, a first portion of the oxide material and a second portion of the mold material to form a first cavity;
removing, in a second direction and using the first cavity, a third portion of the mold material to form a second cavity connected with the first cavity, wherein the second cavity extends between a bottom surface of the oxide material and a top surface of the structure; and
forming an electrode material in the first cavity and the second cavity, the electrode material coupled with the selector device.

2. The method of claim 1, wherein at least a portion of the third portion of the mold material is aligned in the vertical direction with at least a portion of the selector device.

3. The method of claim 1, wherein:
removing the third portion of the mold material exposes at least a portion of the selector device; and
forming the electrode material causes the electrode material to couple with the at least the portion of the selector device.

4. The method of claim 1, further comprising:
removing, after forming the electrode material, the oxide material to form a third cavity;
lining the third cavity with a dielectric material after removing the oxide material; and
filling a remainder of the third cavity with a second electrode material after lining the third cavity with the dielectric material.

5. The method of claim 4, further comprising:
heating the mold material to alter a crystalline structure of the mold material before removing the oxide material.

6. The method of claim 4, wherein:
the electrode material comprises a bottom electrode coupled with the selector device; and
the second electrode material comprises a top electrode associated with a plate line.

7. The method of claim 1, further comprising:
removing, after forming the electrode material, the oxide material and the mold material to form a third cavity;
lining the third cavity with a dielectric material after removing the oxide material; and
filling a remainder of the third cavity with a second electrode material after lining the third cavity with the dielectric material.

8. The method of claim 1, wherein removing the first portion of the oxide material and the second portion of the mold material comprises:
performing an etching process on the first portion of the oxide material and the second portion of the mold material; and
stopping the etching process before etching through the mold material.

9. The method of claim 1, wherein removing the third portion of the mold material comprises:
performing a chemically selective etch on the mold material.

10. The method of claim 1, wherein forming the electrode material comprises:
performing atomic layer deposition of the electrode material within the first cavity and the second cavity.

11. The method of claim 1, wherein:
the mold material comprises an amorphous aluminum oxide material or a carbon material; and
the electrode material comprises a titanium nitride material.

12. The method of claim 1, wherein the third portion of the mold material comprises a ring of the mold material that surrounds the first cavity.

13. An apparatus, comprising:
a memory cell comprising:
a first electrode comprising a pillar having a first width and a base having a second width greater than the first width, the base and the pillar sharing a crystalline structure;
a second electrode; and
a dielectric material positioned between the first electrode and the second electrode, the dielectric material electrically insulating the first electrode from the second electrode; and
a selector device for the memory cell, the selector device coupled with the base of the first electrode of the memory cell.

14. The apparatus of claim 13, wherein the pillar of the first electrode has a first height, and wherein the base of the first electrode comprises a pillar having a second height less than the first height.

15. The apparatus of claim 13, wherein at least a portion of the base of the first electrode is electrically coupled with at least a portion of the selector device.

16. The apparatus of claim 13, further comprising:
a second memory cell comprising:
a third electrode comprising a second pillar having a third width and a second base having a fourth width greater than the third width, the second base and the second pillar sharing a crystalline structure;
a portion of the second electrode; and
a portion of the dielectric material, the portion of the dielectric material positioned between the third electrode and the portion of the second electrode and electrically insulating the third electrode from the second electrode; and
a second selector device for the second memory cell, the second selector device coupled with the base of the third electrode of the second memory cell.

17. The apparatus of claim 16, further comprising:
a mold material occupying a space between the base of the first electrode and the second base of the third electrode, the mold material below the dielectric material.

18. The apparatus of claim 17, wherein the mold material comprises an oxide material or a carbon material.

19. The apparatus of claim 16, wherein the dielectric material occupies a space between the base of the first electrode and the second base of the third electrode.

20. The apparatus of claim 13, wherein the crystalline structure of the first electrode is uninterrupted between the pillar and the base along a center line of the first electrode.

21. The apparatus of claim 13, wherein the crystalline structure of the first electrode comprises an edge grain structure that follows a first surface between the pillar and the dielectric material and a second surface between the base and the dielectric material, the edge grain structure extending from the first surface to the second surface.

22. The apparatus of claim 13, wherein:
the first electrode comprises a titanium nitride material; and
the dielectric material comprises a ferroelectric material.

23. A method, comprising:
forming a structure comprising a plurality of selector devices;
forming, above the structure, a mold material;
forming, above the mold material, an oxide material;
removing, in a vertical direction, a first portion of the oxide material and a second portion of the mold material to form a plurality of first cavities;
removing, in a second direction and using the plurality of first cavities, a third portion of the mold material to form a plurality of second cavities each connected with a respective first cavity, wherein each second cavity extends between a bottom surface of the oxide material and a top surface of the structure; and
forming a plurality of electrode materials, each electrode material formed in a respective first cavity and a respective second cavity, and each electrode material coupled with a respective selector device.

24. The method of claim 23, further comprising:
removing, after forming the plurality of electrode materials, the oxide material to form a plurality of third cavities;
lining each of the plurality of third cavities with a dielectric material after removing the oxide material; and
filling a respective remainder of each of the plurality of third cavities with a second electrode material after lining the plurality of third cavities with the dielectric material.

25. The method of claim 23, further comprising:
removing, after forming the plurality of electrode materials, the oxide material and the mold material to form a plurality of third cavities;
lining each of the plurality of third cavities with a dielectric material after removing the oxide material; and
filling a respective remainder of each of the plurality of third cavities with a second electrode material after lining the plurality of third cavities with the dielectric material.
